(19) United States
(12) Patent Application Publication
(10) Pub. No.: US 2024/0260392 A1
(43) Pub. Date: Aug. 1, 2024

(54) DISPLAY APPARATUS

(71) Applicant: LG Display Co., Ltd., Seoul (KR)

(72) Inventors: Sang-Mo BYUN, Paju-si (KR); Hyun KIM, Paju-si (KR); Chul-Young JANG, Paju-si (KR); Da-Yeon JEONG, Paju-si (KR)

(73) Assignee: LG Display Co., Ltd., Seoul (KR)

(21) Appl. No.: 18/394,754

(22) Filed: Dec. 22, 2023

(30) Foreign Application Priority Data
Jan. 30, 2023 (KR) 10-2023-0011678

(51) Int. Cl. H10K 59/80; H10K 59/122

(52) U.S. Cl. CPC H10K 59/80523; H10K 59/122; H10K 59/80515

(57) ABSTRACT

A display apparatus includes a first subpixel, a second subpixel and a third subpixel disposed on a substrate; a first organic light emitting element configured to emit a first color of light, a second organic light emitting element configured to emit a second color of light and a third organic light emitting element configured to emit a third color of light disposed in the first, second and third subpixels, respectively; a first anode, a second anode and a third anode disposed in the first, second and third subpixels, respectively; and a first cathode, a second cathode and a third cathode disposed in the first, second and third subpixels, respectively, wherein the first, second and third cathodes include at least one layer, and wherein at least two cathodes among the first, second and third cathodes have a different number of layers than each other.

### CROSS REFERENCE TO RELATED APPLICATIONS

The present application claims priority to Korean Patent Application No. 10-2023-0011678 filed in Republic of Korea on Jan. 30, 2023, which is hereby incorporated by reference in its entirety for all purposes as if fully set forth herein.

### BACKGROUND

### Field of the Invention

The present invention relates to a display apparatus with improved light extraction efficiency.

### Discussion of the Related Art

Recently, an importance of display apparatuses has increased with development of multimedia. In response to this, flat panel display apparatuses such as a liquid crystal display apparatus, a plasma display apparatus, and an organic electroluminescent display apparatus have been commercialized. Among these display apparatuses, the organic electroluminescent display apparatus has been currently widely used because it has a high response speed, a high brightness, and a good viewing angle.

However, the organic electroluminescent display apparatus has a problem of poor light extraction efficiency. Moreover, in the situation of the organic electroluminescent display apparatus that implements images using red (R), green (G), and blue (B) light emitting elements, there is a problem in that a light extraction efficiency is 10% or less. Also, forming red (R), green (G), and blue (B) subpixels to have different structures often includes numerous processing steps which increases manufacturing costs and is not eco-friendly.

### SUMMARY OF THE DISCLOSURE

Accordingly, the present invention is directed to a display apparatus that substantially obviates one or more of the problems due to limitations and disadvantages of the related art.

An advantage of the present invention is to provide a display apparatus with improved light extraction efficiency.

An advantage of the present invention is to provide a display apparatus which can simplify processes and reduce production cost by patterning an electrode of an organic light emitting element using a metal patterning layer.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a display apparatus includes: a first subpixel, a second subpixel and a third subpixel disposed on a substrate; a first organic light emitting element configured to emit a first color of light, a second organic light emitting element configured to emit a second color of light and a third organic light emitting element configured to emit a third color of light disposed in the first, second and third subpixels, respectively; a first anode, a second anode and a third anode disposed in the first, second and third subpixels, respectively; and a first cathode, a second cathode and a third cathode disposed in the first, second and third subpixels, respectively, wherein the first, second and third cathodes include at least one layer, and wherein at least two cathodes among the first, second and third cathodes have a different number of layers than each other.

In another aspect, a display apparatus includes: a first subpixel, a second subpixel and a third subpixel disposed on a substrate; a first electrode disposed in each of the first, second and third subpixels; an organic layer disposed on the first electrode in each of the first, second and third subpixels; a second electrode disposed on the organic layer in each of the first, second and third subpixels, the second electrode including at least one layer; and a metal patterning layer disposed on the second electrode of at least one subpixel among the first, second and third subpixels.

In yet another aspect, a display apparatus includes: a first subpixel and a second subpixel disposed on a substrate; a first anode and a second anode disposed in the first and second subpixels, respectively; a first organic light emitting element configured to emit a first color of light disposed in the first subpixel; a second organic light emitting element configured to emit a second color of light disposed in the second subpixel; and a first cathode and a second cathode disposed in the first and second subpixels, respectively, wherein the first cathode has a different number of layers than the second cathode.

It is to be understood that both the foregoing general description and the following detailed description are explanatory examples and are intended to provide further explanation of the invention as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a schematic block diagram illustrating a display apparatus according to an embodiment of the present invention;

FIG. 2 is a schematic block diagram illustrating a subpixel shown in FIG. 1 according to an embodiment of the present invention;

FIG. 3 is a circuit diagram conceptually illustrating a subpixel of an organic light emitting display apparatus according to an embodiment of the present invention;

FIG. 4 is a cross-sectional view conceptually illustrating a structure of a display apparatus according to an embodiment of the present invention;

FIG. 5 is a cross-sectional view specifically illustrating a structure of a display apparatus according to an embodiment of the present invention;

FIGS. 6A to 6F are views illustrating a manufacturing method of a display apparatus according to an embodiment the present invention;

FIG. 7 is a cross-sectional view illustrating a display apparatus according to another embodiment of the present invention;

FIG. 8 is a cross-sectional view illustrating a display apparatus according to an embodiment of the present invention;

FIG. 9 is a cross-sectional view illustrating a display apparatus according to an embodiment of the present invention;

FIG. 10 is a cross-sectional view illustrating a display apparatus according to an embodiment of the present invention; and

FIG. 11 is a cross-sectional view illustrating a display apparatus according to an embodiment of the present invention.

### DETAILED DESCRIPTION OF THE EMBODIMENTS

Advantages and features of the present invention and methods of achieving them can be apparent with reference to the embodiments described below in detail with the accompanying drawings. However, the present invention is not limited to the embodiments disclosed below, but can be realized in a variety of different forms, and only these embodiments allow the present invention to be complete. The present invention can be provided to fully inform the scope of the invention to the skilled in the art of the present invention, and the present invention can be defined by the scope of the claims.

The shapes, sizes, proportions, angles, numbers, and the like disclosed in the drawings for explaining the embodiments of the present invention are illustrative, and the present invention is not limited to the illustrated matters. The same reference numerals can refer to the same components throughout the description.

Furthermore, in describing the present invention, if it is determined that a detailed description of the related known technology unnecessarily obscure the subject matter of the present invention, the detailed description thereof can be omitted. When “comprising,” “including,” “having,” “consisting,” and the like are used in this invention, other parts can be added unless ‘only’ is used. When a component is expressed in the singular, situations including the plural are included unless specific statement is described.

In interpreting the components, even if there is no separate explicit description, it is interpreted as including a margin range.

In the situation of a description of a positional relationship, for example, when the positional relationship of two parts is described as “on,” “over,” “above,” “below,” “beside,” “under,” and the like, one or more other parts can be positioned between such two parts unless “right” or “directly” is used.

In the situation of a description of a temporal relationship, for example, when a temporal precedence is described as “after,” “following,” “before,” and the like, situations that are not continuous can be included unless “directly” or “immediately” is used.

Respective features of various embodiments of the present invention can be partially or wholly connected to or combined with each other and can be technically interlocked and driven variously, and respective embodiments can be independently implemented from each other or can be implemented together with a related relationship.

In describing components of the present invention, terms such as first, second, A, B, (a), (b) and the like can be used. These terms are only for distinguishing the components from other components, and an essence, order, order, or number of the components is not limited by the terms. Further, when it is described that a component is “connected,” “coupled” or “contact” to another component, the component can be directly connected or contact the another component, but it should be understood that other component can be “interposed” between the components.

“At least one” should be understood to include all combinations of one or more of associated components. For example, meaning of “at least one of first, second, and third components” means not only the first, second, or third component, but also all combinations of two or more of the first, second and third components.

In this invention, a “display apparatus” can include a display apparatus in a narrow sense, such as a display module including a display panel and a driving portion for driving the display panel. Furthermore, the “display apparatus” can include a complete product or final product including a display module which is a notebook computer, a television, a computer monitor, an automotive display or equipment display including other type of vehicle, or a set electronic device or set device or set apparatus such as a mobile electronic device which is a smart phone, an electronic pad or the like.

Therefore, the apparatus of this invention can include a display apparatus itself such as a display module, and an application product or a set device that is an end-user device, including a display module.

Hereinafter, embodiments of the present invention are described in detail with reference to the drawings.

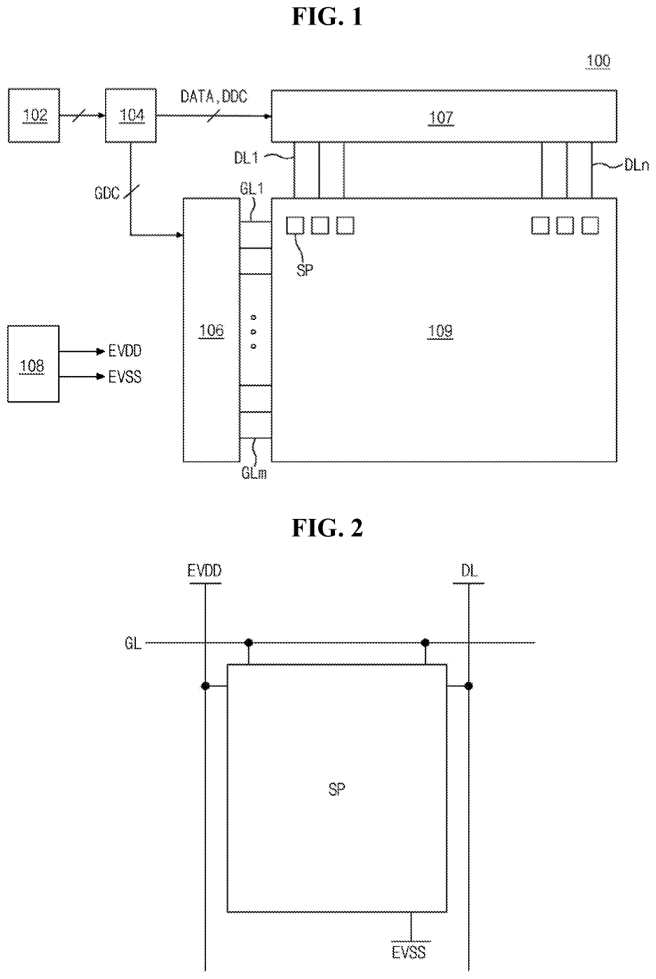

FIG. 1 is a schematic block diagram illustrating a display apparatus according to an embodiment of the present invention, and FIG. 2 is a schematic block diagram illustrating a subpixel shown in FIG. 1.

As shown in FIG. 1, the display apparatus 100 can include an image processing portion 102, a timing control portion 104 (e.g., a timing controller), a gate driving portion 106 (e.g., a gate driver), a data driving portion 107 (e.g., a data driver), a power supply portion 108 (e.g., a power supply), and a display panel 109.

The image processing portion 102 can output image data supplied from an outside and driving signals for driving various components. For example, the driving signals output from the image processing portion 102 can include a data enable signal, a vertical synchronization signal, a horizontal synchronization signal, and a clock signal.

The timing control portion 104 can receive the image data and the driving signals from the image processing portion 102. The timing control portion 104 can generate and output a gate timing control signal GDC for controlling operation timing of the gate driving portion 106 and a data timing control signal DDC for controlling operation timing of the data driving portion 107 based on the driving signals input from the image processing portion 102.

The gate driving portion 106 can outputs scan signals to the display panel 109 in response to the gate timing control signal GDC supplied from the timing control portion 104. The gate driving portion 106 can outputs the scan signals through a plurality of gate lines GL1 to GLm. The gate driving portion 106 can be formed in a form of an IC (Integrated Circuit), but not limited thereto.

The data driving portion 107 can output data voltages to the display panel 109 in response to the data timing control signal DDC input from the timing control portion 104. The data driving portion 107 can sample and latch digital data signals DATA supplied from the timing control portion 104 and convert the data signals DATA into analog data voltages based on gamma voltages. The data driving portion 107 can output the data voltages through a plurality of data lines DL1 to DLn. The data driving portion 107 can be formed in a form of an IC (Integrated Circuit), but not limited thereto.

The power supply portion 108 can output and supply a high potential voltage (VDD) and a low potential voltage (VSS) to the display panel 109. The high potential voltage (VDD) can be supplied to the display panel 109 through a first power line EVDD, and the low potential voltage (VSS) can be supplied to the display panel 109 through a second power line EVSS. Voltages output from the power supply portion 108 can be output to the gate driving portion 106 and/or the data driving portion 107 and used to drive them.

The display panel 109 can display images in response to the data voltages and the scan signals supplied from the data driving portion 107 and the gate driving portion 106, and the voltages supplied from the power supply portion 108.

The display panel 109 can include a plurality of subpixels SP to display an actual image. The subpixels SP can include a red subpixel, a green subpixel, and a blue subpixel, or a white subpixel, a red subpixel, a green subpixel, and a blue subpixel. The white, red, green, and blue subpixels SP can all be formed with the same area, or can be formed with different areas.

As shown in FIG. 2, one subpixel SP can be connected to the gate line GL, the data line DL, the first power line EVDD, and the second power line EVSS. A driving method of the subpixel SP and a number of transistors and capacitors of the subpixel SP can be determined depending on a configuration of a pixel circuit of the subpixel SP.

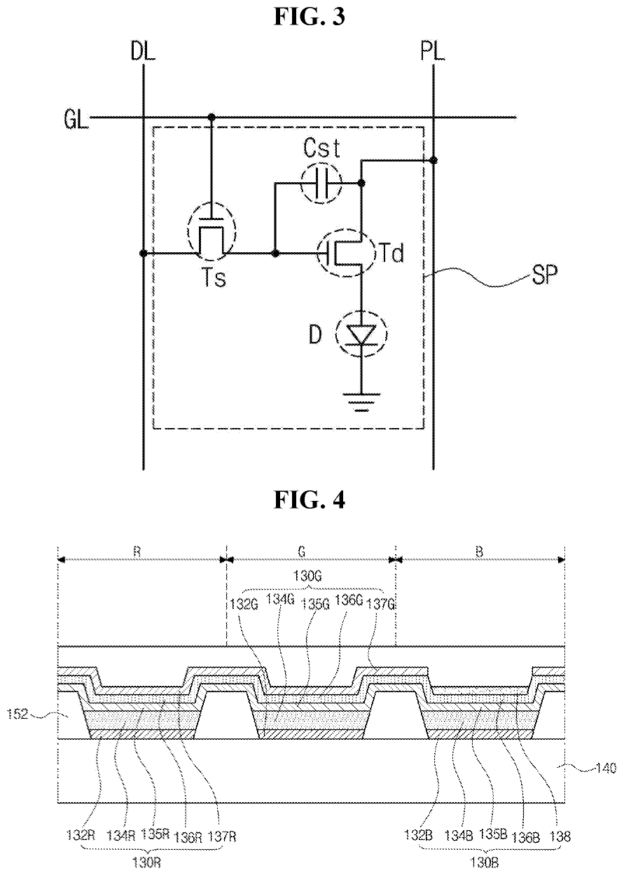

FIG. 3 is a circuit diagram conceptually illustrating a subpixel of an organic light emitting display apparatus according to the present invention.

As shown in FIG. 3, the organic light emitting display apparatus according to the present invention can include the gate line GL, the data line DL, and the power line (or first power line) PL that cross each other to define the subpixel SP. In the subpixel SP, a switching thin film transistor Ts, a driving thin film transistor Td, a storage capacitor Cst, and an organic light emitting element D can be disposed.

The switching thin film transistor Ts can be connected to the gate line GL and the data line DL, and the driving thin film transistor Td and storage capacitor Cst can be connected between the switching thin film transistor Ts and the power line PL. The organic light emitting element D can be connected to the driving thin film transistor Td.

In the organic light emitting display apparatus of this structure, when the switching thin film transistor Ts is turned on according to the gate signal applied to the gate line GL, the data signal applied to the data line DL is applied to a gate electrode of the driving thin film transistor Td and one electrode of the storage capacitor Cst through the switching thin film transistor Ts.

The driving thin film transistor Td is turned on according to the data signal applied to the gate electrode thereof, and as a result, a current proportional to the data signal flows from the power line PL to the organic light emitting element D through the driving thin film transistor Td. The organic light emitting element D emits light with a luminance proportional to the current flowing through the driving thin film transistor Td.

At this time, the storage capacitor Cst is charged with a voltage proportional to the data signal, so that the voltage of the gate electrode of the driving thin film transistor Td is maintained constant during one frame.

In the drawing, only two thin film transistors Td and Ts and one capacitor Cst are provided, but the present invention is not limited to this and three or more thin film transistors and two or more capacitors can be provided.

FIG. 4 is a cross-sectional view conceptually illustrating a structure of a display apparatus according to a first embodiment of the present invention. The display apparatus 100 can be categorized into a top emission type display apparatus in which light is output in the upward direction and a bottom emission type display apparatus in which a light is output in the downward direction. However, for convenience of explanation, the top emission type display apparatus is taken as an example.

As shown in FIG. 4, the display apparatus 100 according to the first embodiment of the present invention can include R, G, and B subpixels, and a bank layer 152 can be formed in a boundary region between the R, G, and B subpixel and partition R, G, and B subpixels. The bank layer 152 can be formed in a matrix shape with a set width in the boundary region between the R, G, and B subpixels on the substrate 140, and the bank layer 152 can include an opening exposing each of the R, G, and B subpixels to the outside.

Organic light emitting elements 130R, 130G, and 130B can be disposed in the R, G, and B subpixels exposed through the openings of the bank layer 152, respectively.

An R (e.g., red) organic light emitting element 130R can include a 1R (or first R) electrode 132R, an R organic layer 134R disposed on the 1R electrode 132R, a 2R (or second R) electrode 135R disposed on the R organic layer 134R, a 3R (or third R) electrode 136R disposed on the 2R electrode 135R, and a 4R (or fourth R) electrode 137R disposed on the 3R electrode 136R.

A G (e.g., green) organic light emitting element 130G can include a 1G (or first G) electrode 132G, a G organic layer 134G disposed on the 1G electrode 132G, a 2G (or second G) electrode 135G disposed on the G organic layer 134G, a 3G (or third G) electrode 136G disposed on the 2G electrode 135G, and a 4G (or fourth G) electrode 137G disposed on the 3G electrode 136G.

A B (e.g., blue) organic light emitting element 130B can include a 1B (or first B) electrode 132B, a B organic layer 134B disposed on the 1B electrode 132B, a 2B (or second B) electrode 135B disposed on the B organic layer 134B, a 3B (or third B) electrode 136B disposed on the 2B electrode 135B, and a metal patterning layer 138 disposed on the 3B electrode 136B.

The 1R electrode 132R of the R organic light emitting element 130R, the 1G electrode 132G of the G organic light emitting element 130G, and the 1B electrode 132B of the B organic light emitting element 130B can be anode electrodes.

The 2R electrode 135R, the 3R electrode 136R, and the 4R electrode 137R of the R organic light emitting element 130R, the 2G electrode 135G, the 3G electrode 136G, and the 4G electrode 137G of the G organic light emitting element 130G, and the 2B electrode 135B and the 3B electrode 136B of the B organic light emitting element 130B can be cathode electrodes. For example, the cathodes of the R organic light emitting element 130R and the G organic light emitting element 130G can have three layers, while the cathode of the B organic light emitting element 130B can have two layers. In other words, the cathode in each of the R organic light emitting element 130R and the G organic light emitting element 130G can have more layers than the cathode in the B organic light emitting element 130B.

The 1R electrode 132R of the R organic light emitting element 130R, the 1G electrode 132G of the G organic light emitting element 130G, and the 1B electrode 132B of the B organic light emitting element 130B can be formed of a metal (e.g., a reflective metal) such as Ca, Ba, Mg, Al, or Ag, or an alloy thereof and reflect light emitted from the corresponding organic layers 134R, 134G, and 134B to improve light efficiency. In addition, the 1R electrode 132R, the 1G electrode 132G, and the 1B electrode 132B can include a transparent metal oxide with a high work function, such as ITO (Indium Tin Oxide) or IZO (Indium Zinc Oxide). In this case, each of the 1R, 1G, and 1B electrodes 132R, 132G, and 132B can further include an opaque conductive material to function as a reflective electrode that reflects light. However, the 1R electrode 132R, the 1G electrode 132G, and the 1B electrode 132B are not limited to the above structure.

The 2R electrode 135R, the 3R electrode 136R, and the 4R electrode 137R of the R organic light emitting element 130R, the 2G electrode 135G, the 3G electrode 136G, and 4G electrode 137G of the G organic light emitting element 130G, and the 2B electrode 135B and the 3B electrode 136B of the B organic light emitting element 130B can be formed of a semi-transmissive conductive layer.

The 2R electrode 135R, the 2G electrode 135G, and the 2B electrode 135B can be formed integrally (e.g., as a common layer across the three subpixels). For example, the 2R electrode 135R, the 2G electrode 135G, and the 2B electrode 135B can be formed of at least one of alloys such as LiF/Al, CsF/Al, Mg:Ag, Ca/Ag, Ca:Ag, LiF/Mg:Ag, LiF/Ca/Ag, and LiF/Ca:Ag. At this time, the 2R electrode 135R, the 2G electrode 135G, and the 2B electrode 135B can be formed to have a thin thickness of about 50 Å to 1500 Å, preferably about 100 Å to 1000 Å (e.g., 550 Å), so that a part of light emitted from each of the R organic layer 134R, the G organic layer 134G, and the B organic layer 134B is transmitted and output upward (e.g., output to the outside of the display apparatus 100), and another part of the light is reflected downward (e.g., reflected inside the display apparatus 100).

The 3R electrode 136R, the 3G electrode 136G, and the 3B electrode 136B can be formed integrally (e.g., as a common layer across the three subpixels). For example, the 3R electrode 136R, the 3G electrode 136G, and the 3B electrode 136B can be formed of a metal such as AgMg, but not limited thereto. At this time, the 3R electrode 136R, the 3G electrode 136G, and the 3B electrode 136B can be formed to have a thin thickness of about 50 Å to 1500 Å, preferably about 100 Å to 1000 Å (e.g., 550 Å), so that a part of light emitted from each of the R organic layer 134R, the G organic layer 134G, and the B organic layer 134B is transmitted and output upward (e.g., output to the outside of the display apparatus 100), and another part of the light is reflected downward (e.g., reflected inside the display apparatus 100).

The 4R electrode 137R and the 4G electrode 137G can be formed integrally (e.g., as a common layer across the two R and G subpixels). For example, the 4R electrode 137R and the 4G electrode 137G can be formed of a metal oxide such as ITO or IZO, but not limited thereto. At this time, the 4R electrode 137R and the 4G electrode 137G can be formed to have a thickness of 50 Å to 4000 Å, preferably about 100 Å to 3000 Å (e.g., 1550 Å).

As described later, the metal patterning layer 138 can be used to pattern the 4R electrode 137R and the 4G electrode 137G. The metal patterning layer 138 can be for patterning the 4R electrode 137R and the 4G electrode 137G of the R subpixel and the G subpixel by a self-aligning patterning method. In this regard, without a separate etching process of a metal layer, based on an interface characteristics with the metal patterning layer 138, a metal layer deposited can be removed on the metal patterning layer 138 or a metal can be prevented from being deposited on the metal patterning layer 138, thereby patterning the metal layer.

Accordingly, the metal patterning layer 138 can be made of an organic material with low surface energy or low adhesion to metal. In other words, a metal layer does not stick well to the metal patterning layer 138.

Due to the characteristics of the metal patterning layer 138, when a metal layer is deposited, a probability of desorption of a metal from a surface of the metal patterning layer 138 is very high, so that nucleation of the deposited metal atoms does not occur. In other words, metal patterning layer 138 has a type of “metalphobic” property. Thus, when depositing a metal layer, the metal is not deposited on an upper surface (or top surface) of the metal patterning layer 138, but is deposited only in other regions excluding the metal patterning layer 138, and thus the metal layer can be formed only on the R and G subpixels and the bank layer 152. Therefore, the 4R electrode 137R and the 4G electrode 137G are formed in the R and G subpixels, respectively, but a 4B electrode is not formed in the B subpixel due to being block or prevented by the metal patterning layer 138.

As such, in the display apparatus 100 according to an embodiment of the present invention, three electrodes 135R, 136R, and 137R, and 135G, 136G, and 137G can be disposed on the organic layers 134R and 134G in the R subpixel and the G subpixel, respectively, but in the B subpixel, only two electrodes 135B and 136B can be disposed on the organic layer 134B, and the reason for this is explained in detail below. In other words, the cathodes of the R organic light emitting element 130R and the G organic light emitting element 130G can have three layers, while the cathode of the B organic light emitting element 130B can have two layers.

In the situation of a display device equipped with organic light emitting elements, especially when it is equipped with R, G, and B light emitting elements to emit red light, green light, and blue light to display an image, a light extraction efficiency is 10% or less. Thus, in order to implement an image of a desired color, a current applied to the organic light emitting element should be increased. In this situation, there are problems that power consumption increases and a lifespan of the device decreases due to deterioration of an organic layer.

However, the display apparatus 100 according to an embodiment of the present invention can improve light extraction efficiency by using a cavity effect (e.g., a microcavity effect). In the situation of a top emission type display apparatus, the 1R electrode 132R, the 1G electrode 132G, and the 1B electrode 132B that are the anode electrodes can be formed of a metal or metal alloy that reflects light emitted from the organic layers 134R, 134G, and 134B. In addition, the 2R electrode 135R, the 2G electrode 135G, the 2B electrode 135B, the 3R electrode 136R, the 3G electrode 136G, the 3B electrode 136B, the 4R electrode 137R, and the 4G electrode 137G that are the cathode electrodes can be formed of a thin metal layer and/or a transparent metal oxide that transmits a part of light emitted from the organic layers 134R, 134G, and 134B and reflects another part of the light.

Conversely, in the situation of a bottom emission type display apparatus, the 1R electrode 132R, the 1G electrode 132G, and the 1B electrode 132B that are the anode electrodes can be formed of a thin metal layer and/or a transparent metal oxide that transmits a part of light emitted from the organic layers 134R, 134G, and 134B and reflects another part of the light. In addition, the 2R electrode 135R, the 2G electrode 135G, the 2B electrode 135B, the 3R electrode 136R, the 3G electrode 136G, the 3B electrode 136B, and the 4R electrode 137R, and the 4G electrode 137G that are the cathode electrodes can be formed of a metal or metal alloy that reflects light emitted from the organic layers 134R, 134G, and 134B.

In the situation of the top emission type display apparatus 100, the light emitted from the organic layer 134R, 134G, or 134B and output downward is reflected by the anode electrode and propagates back upward, and a part of the light emitted upward is reflected by the cathode electrode and propagates downward and another part of the light emitted upward is output to the outside. The light reflected from the anode electrode and the cathode electrode undergoes constructive interference and is output to the outside (e.g., an enhancement effect), thereby improving light extraction efficiency.

According to an embodiment of the present invention, light extraction efficiency can be further improved by varying a degree of constructive interference for each of the R, G, and B subpixels. The constructive interference of light varies depending on wavelength and resonance distance of light. In other words, when the resonance distance is the same, the degree of constructive interference for the wavelength of light varies. For example, since the degrees of constructive interference of red light, green light, and blue light are different at a specific resonance distance, there is a difference in light extraction efficiency due to constructive interference between the R, G, and B subpixels.

According to an embodiment of the present invention, by setting the resonance distance differently for each of the R, G, and B subpixels, the constructive interference of each of the red light, the green light, and the blue light can be maximized, thereby individually optimizing the light extraction efficiency for each of the R, G, and B subpixels.

The resonance distance of light in the display apparatus 100 is a distance reflected within each of the organic light emitting elements 130R, 130G, and 130B, that is, a distance between the anode electrode and the cathode electrode. According to an embodiment of the present invention, the light extraction efficiency can be optimized by varying the distance between the anode electrode and the cathode electrode for each of the R, G, and B subpixels.

In other words, the 4R electrode 137R and the 4G electrode 137G are respectively formed in the R subpixel and the G subpixel which emit the red light and the green light with relatively long wavelengths, and a 4B electrode is not formed in the B subpixel which emits the blue light with a relatively short wavelength. Accordingly, in the R and G subpixels where the lights with long wavelengths constructively interfere, the resonance distances increase by the thickness of the 4R electrode 137R and the 4G electrode 137G, respectively, and the constructive interferences are maximized. In the B subpixel where the light with short wavelength constructively interferes, the resonance distance is shortened, and the constructive interference is maximized.

As such, according to an embodiment of the present invention, by varying a number of the cathode electrodes formed in the R, G, and B subpixels, the resonance distance for each wavelength of light is individually adjusted and optimized, thereby maximizing the constructive interference for each wavelength for the different colors. Therefore, the light extraction efficiency in the R, G, and B subpixels can be maximized.

In addition, according to an embodiment of the present invention, since the 4R electrode 137R and the 4G electrode 137G are formed using the metal patterning layer 138, a separate photolithography process is not required. Therefore, the manufacturing processes can be simplified, costs can be reduced, and by eliminating the use of harmful substances such as etchant or developer, it becomes possible to be eco-friendly.

Hereinafter, the display apparatus 100 according to the first embodiment of the present invention is described in more detail with reference to the attached drawings.

FIG. 5 is a cross-sectional view specifically illustrating a structure of a display apparatus according to a first embodiment of the present invention. As shown in FIG. 5, the display apparatus 100 can include R, G, and B subpixels.

A buffer layer 142 can be formed on a substrate 140. The substrate 140 can be formed of a hard material such as glass, or a plastic-based material such as polyimide, polymethylmethacrylate, polyethylene terephthalate, polyethersulfone, or polycarbonate, but not limited thereto.

For example, when the substrate 140 is formed of polyimide, the substrate 140 can be formed with a plurality of layers made of polyimides, and an inorganic layer can be disposed between the layers of polyimides, but not limited thereto.

The buffer layer 142 can be formed over the entire substrate 140 and serve to improve adhesion between layers formed thereon and the substrate 140 and to block various types of defects caused by alkaline components or the like flowing out from the substrate 140. In addition, the buffer layer 142 can delay diffusion of moisture or oxygen that penetrates into the substrate 140.

The buffer layer 142 can be made of a single layer or multiple layers using one or more of SiNx and SiOx. When the buffer layer 142 is formed of multiple layers, SiOx and SiNx can be formed alternately. The buffer layer 142 can be omitted based on type and material of the substrate 140, structure and type of the thin film transistor, etc.

Thin film transistors T can be formed on the buffer layer 142 in each of the R, G, and B subpixels. For convenience of explanation, only a driving thin film transistor is shown among various thin film transistors T that can be disposed in each of the R, G, and B subpixels, but other thin film transistor such as a switching thin film transistor can also be included. In addition, in the drawing, the thin film transistor T is described as having a top gate structure, but is not limited to this structure and can be implemented in other structure such as a bottom gate structure or a dual gate structure.

Each thin film transistor T can include a semiconductor pattern (or semiconductor layer) 112 disposed on the buffer layer 142, a gate insulating layer 144 formed on the semiconductor pattern 112, a gate electrode 113 disposed on the gate insulating layer 144, an interlayered insulating layer 146 formed on the gate electrode 113, and a source electrode 114 and a drain electrode 115 disposed on the interlayered insulating layer 146.

The semiconductor pattern 112 can be made of a polycrystalline semiconductor. For example, a polycrystalline semiconductor can be formed of low temperature polysilicon (LTPS) with high mobility, but not limited thereto.

Alternatively, the semiconductor pattern 112 can be made of an oxide semiconductor. For example, the semiconductor pattern 112 can be made of any one of IGZO (Indium-gallium-zinc-oxide), IZO (Indium-zinc-oxide), IGTO (Indium-gallium-tin-oxide), and IGO (Indium-gallium-oxide), but not limited thereto. The semiconductor pattern 112 can include a channel region 112a in a central portion, and a source region 112b and a drain region 112c, which are doped regions, on both sides.

The gate insulating layer 144 can be formed in a display region and a non-display region, or can be formed only in the display region. The gate insulating layer 144 can be formed of a single layer or multiple layers using one or more of inorganic materials such as SiOx and SiNx, but not limited thereto.

The gate electrode 113 can be made of metal. For example, the gate electrode 113 can be formed of a single layer or multiple layers using one or more of molybdenum (Mo), aluminum (Al), chromium (Cr), gold (Au), titanium (Ti), nickel (Ni), neodymium (Nd), copper (Cu), and an alloy thereof, but not limited thereto.

The interlayered insulating layer 146 can be formed in the display region and the non-display region, or can be formed only in the display region. The interlayered insulating layer 146 can be formed of a single layer or multiple layers using an organic material such as photo acrylic, or an inorganic material such as SiNx or SiOx. Alternatively, the interlayered insulating layer 146 can be formed of multiple layers using the organic material layer and the inorganic material layer, but not limited thereto.

The source electrode 114 and drain electrode 115 can be formed of a single layer or multiple layers using one or more of molybdenum (Mo), aluminum (Al), chromium (Cr), gold (Au), titanium (Ti), nickel (Ni), neodymium (Nd), copper (Cu), and an alloy thereof, but not limited thereto. The source electrode 114 and the drain electrode 115 can be connected to the source region 112b and drain region 112c of the semiconductor pattern 112 through contact holes formed in the gate insulating layer 144 and the interlayered insulating layer 146, respectively.

Also, a bottom shield metal layer can be disposed below the semiconductor pattern 112 and on the substrate 140. The bottom shield metal layer can serve to prevent afterimages or deterioration of transistor performance by minimizing a back channel phenomenon caused by charges trapped at the substrate 140, and can be formed of a single layer or multiple layers using one or more of titanium (Ti), molybdenum (Mo), and an alloy thereof, but not limited thereto. Also, a second gate electrode can be formed under the semiconductor pattern 112 (e.g., a TFT with a dual gate structure). In addition, the second gate electrode can also protect or prevent deterioration of the transistor.

A planarization layer 148 can be formed on the substrate 140 on which the thin film transistor T is disposed. The planarization layer 148 can be formed of an organic material such as photo acrylic, but not limited thereto and can be formed of a plurality of layers including an inorganic layer and an organic layer.

A bank layer 152 can be formed at the boundary between the R, G, and B subpixels on the planarization layer 148. The bank layer 152 can be a partition wall that defines the R, G, and B subpixels.

The bank layer 152 can be formed of at least one of an inorganic insulating material such as SiNx or SiOx, an organic insulating material such as BCB (benzocyclobutene), acryl resin, epoxy resin, phenolic resin, polyamide resin, or polyimide resin, or a photosensitive agent containing a black pigment, but not limited thereto.

The organic light emitting elements 130R, 130G, and 130B can be disposed in the R, G, and B subpixels, respectively, and can be disposed between the bank layers 152 on the planarization layer 148.

The organic light emitting element 130R of the R subpixel can include the 1R electrode 132R disposed on the planarization layer 148, the R organic layer 134R disposed on the 1R electrode 132R, the 2R electrode 135R disposed on the R organic layer 134R, the 3R electrode 136R disposed on the 2R electrode 135R, and the 4R electrode 137R disposed on the 3R electrode 136R.

In addition, the G organic light emitting element 130G of the G subpixel can include the 1G electrode 132G disposed on the planarization layer 148, the G organic layer 134G disposed on the first G electrode 132G, the 2G electrode 135G disposed on the G organic layer 134G, the 3G electrode 136G disposed on the 2G electrode 135G, and the 4G electrode 137G disposed on the 3G electrode 136G.

In addition, the B organic light emitting element 130B of the B subpixel can include the 1B electrode 132B disposed on the planarization layer 148, the B organic layer 134B disposed on the 1B electrode 132B, the 2B electrode 135B disposed on the B organic layer 134B, the 3B electrode 136B disposed on the 2B electrode 135B, and the metal patterning layer 138 disposed on the 3B electrode 136B.

The 1R electrode 132R of the R organic light emitting element 130R, the 1G electrode 132G of the G organic light emitting element 130G, and the 1B electrode 132B of the B organic light emitting element 130B can be formed of a metal, such as Ca, Ba, Mg, Al, or Ag, or an alloy thereof and reflect light emitted from the respective organic layers 134R, 134G, and 134B. In addition, the 1R electrode 132R, the 1G electrode 132G, and the 1B electrode 132B can include a transparent metal oxide with a high work function, such as ITO (Indium Tin Oxide) or IZO (Indium Zinc Oxide). In this situation, each of the 1R, 1G, and 1B electrodes 132R, 132G, and 132B can further include an opaque conductive material to function as a reflective electrode that reflects light.

Each of the organic layers 134R, 134G, and 134B can include an organic light emitting layer, or an inorganic light emitting layer, e.g., a nano-sized material layer, quantum dots, a micro LED light emitting layer, or a mini LED light emitting layer, but not limited thereto.

Each of the organic layers 134R, 134G, and 134B can each include not only a light emitting layer, but also an electron injection layer and a hole injection layer which respectively inject electrons and holes into the light emitting layer, and an electron transport layer, a hole blocking layer, an electron blocking layer, and a hole transport layer which respectively transport the injected electrons and holes to the light emitting layer, and not limited thereto.

The 2R electrode 135R, the 3R electrode 136R, and the 4R electrode 137R of the R organic light emitting element 130R, the 2G electrode 135G, the 3G electrode 136G, and the 4th G electrode 137G of the G organic light emitting element 130G, and the 2B electrode 135B and the 3B electrode 136B of the B organic light emitting element 130B can be formed of a semi-transmissive conductive layer.

The 2R electrode 135R, the 2G electrode 135G, and the 2B electrode 135B can be formed integrally (e.g., as a common layer across the three subpixels). Accordingly, the 2R electrode 135R, the 2G electrode 135G, and the 2B electrode 135B can also be formed on the upper surface of the bank layer 152. For example, the 2R electrode 135R, the 2G electrode 135G, and the 2B electrode 135B can be formed of at least one of LiF/Al, CsF/Al, Mg:Ag, Ca/Ag, Ca:Ag, LiF/Mg:Ag, LiF/Ca/Ag, and LiF/Ca:Ag. At this time, the 2R electrode 135R, the 2G electrode 135G, and the 2B electrode 135B can be formed to have a thin thickness of about 50 Å to 1500 Å, preferably about 100 Å to 1000 Å, so that a part of light emitted from each of the R organic layer 134R, the G organic layer 134G, and the B organic layer 134B is transmitted and output upward (e.g., output to the outside of the display apparatus 100), and another part of the light is reflected downward (e.g., reflected inside the display apparatus 100).

The 3R electrode 136R, the 3G electrode 136G, and the 3B electrode 136B can be formed integrally (e.g., as a common layer across the three subpixels). Accordingly, the 3R electrode 136R, the 3G electrode 136G, and the 3B electrode 136B can also be formed on the bank layer 152. For example, the 3R electrode 136R, the 3G electrode 136G, and the 3B electrode 136B can be formed of a metal such as AgMg, but not limited thereto. At this time, the 3R electrode 136R, the 3G electrode 136G, and the 3B electrode 136B can be formed to have a thin thickness of about 50 Å to 1500 Å, preferably about 100 Å to 1000 Å (e.g., 550 Å), so that a part of light emitted from each of the R organic layer 134R, the G organic layer 134G, and the B organic layer 134B is transmitted and output upward (e.g., output to the outside of the display apparatus 100), and another part of the light is reflected downward (e.g., reflected inside the display apparatus 100).

The 4R electrode 137R and the 4G electrode 137G can be formed integrally (e.g., as a common layer across the R and G subpixels). For example, the 4th R electrode 137R and the 4th G electrode 137G can be formed of a metal oxide such as ITO or IZO, but is not limited thereto. At this time, the 4th R electrode 137R and the 4th G electrode 137G can be formed to have a thickness of about 50 Å to 4000 Å, preferably about 100 Å to 3000 Å (e.g., 1550 Å).

The metal patterning layer 138 can be formed of an organic material with low surface energy or low adhesion to metal. As explained later, the metal patterning layer 138 can be provided to pattern a metal layer using a self-aligned patterning method. In this regard, the metal patterning layer 138 can be provided such that without a separate etching process of a metal layer, based on an interface characteristics with the metal patterning layer 138, a metal layer deposited is removed on the metal patterning layer 138 or a metal is prevented from being deposited on the metal patterning layer 138 (e.g., metal patterning layer 138 can have a type of “metalphobic” property), thereby patterning the metal layer.

As such, since no metal is deposited on the upper surface of the metal patterning layer 138, a metal layer is formed only on the R and G subpixels and the bank layer 152. Thus, the 4R electrode 137R and the 4G electrode 137G are formed in the R and G subpixels, respectively, and a 4B electrode is not formed in the B subpixel.

An encapsulation layer 160 can be formed on the organic light emitting elements 130R, 130G, and 130B. The encapsulation layer 160 can be formed of a first encapsulation layer 162, a second encapsulation layer 164, and a third encapsulation layer 166. The first encapsulation layer 162 and the third encapsulation layer 166 can be made of an inorganic material such as SiOx or SiNx, but not limited thereto. The second encapsulation layer 164 can be made of an organic insulating material such as acrylic resin, epoxy resin, polyimide, polyethylene, or silicon oxycarbon (SiOC), but not limited thereto.

The first encapsulation layer 162 and the third encapsulation layer 166 made of the inorganic material can serve to block penetration of moisture or oxygen, and the second encapsulation layer 164 made of the organic material can serve to flatten a surface of the substrate and prevent cracks from occurring in the encapsulation layer 160 due to an external force.

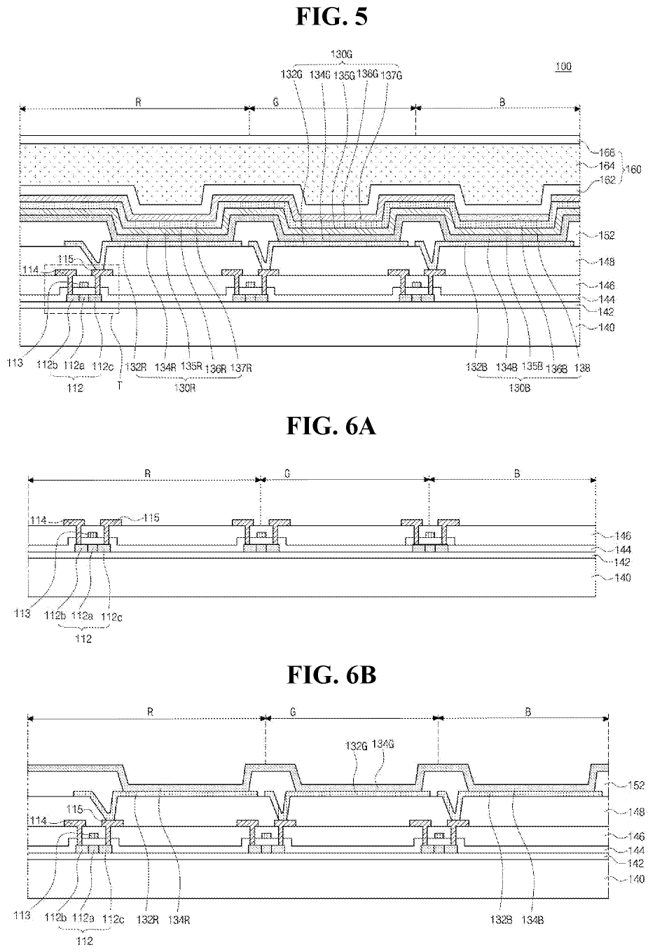

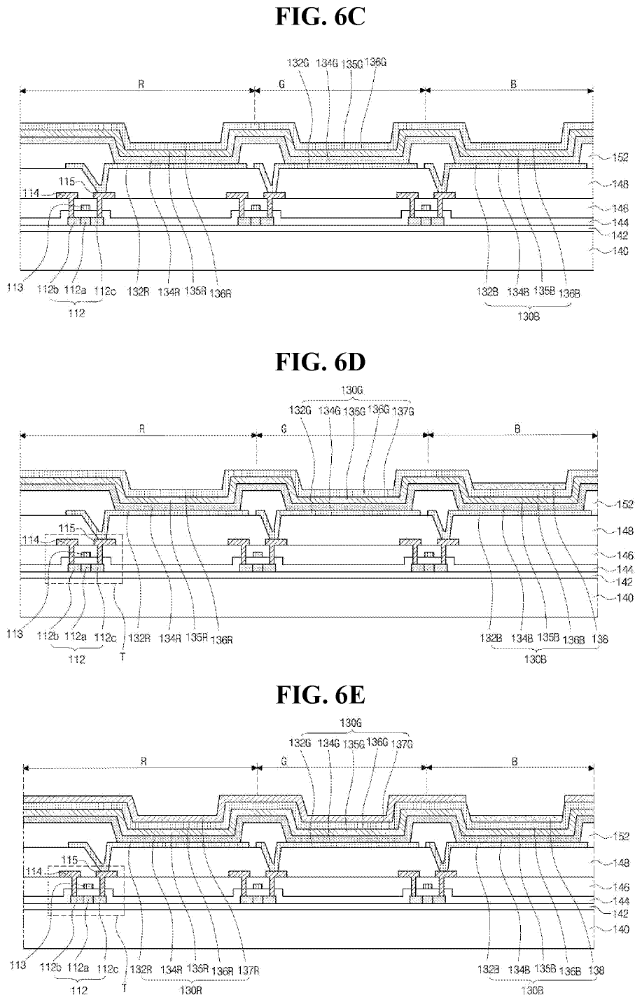

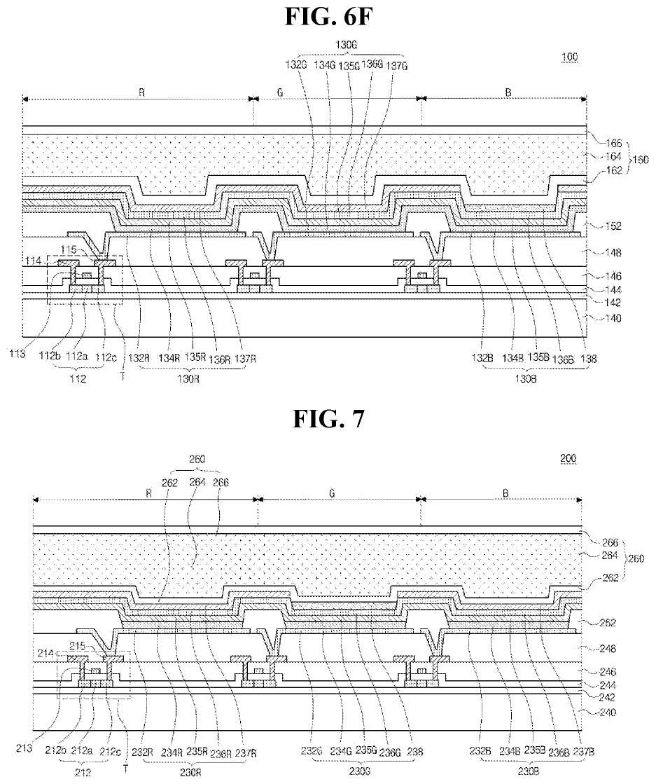

FIGS. 6A to 6F are views illustrating a manufacturing method of a display apparatus according to the present invention.

First, as shown in FIG. 6A, the buffer layer 142 made of a single layer or multiple layers using one or more of SiNx and SiOx can be formed over the entire substrate 140 including the display region and the non-display region, and the substrate can be formed of a hard material such as glass, or a plastic-based material such as polyimide, polymethylmethacrylate, polyethylene terephthalate, polyethersulfone, or polycarbonate.

Next, a polycrystalline semiconductor such as polysilicon, or an oxide semiconductor such as indium-gallium-zinc-oxide (IGZO), indium-zinc-oxide (IZO), indium-gallium-tin-oxide (IGTO), or indium-gallium-oxide (IGO) can be laminated in each of the R, G, and B subpixels on the buffer layer 142 and be etched to form the semiconductor pattern 112 in each of the R, G, and B subpixels. In addition, impurities can be doped on both sides of the semiconductor pattern 112 to form the channel region 112a, the source region 112b, and the drain region 112c.

Then, an inorganic material such as SiOx or SiNx can be laminated to form the gate insulating layer 144. Then, a metal such as molybdenum (Mo), aluminum (Al), chromium (Cr), gold (Au), titanium (Ti), nickel (Ni), neodymium (Nd), or copper (Cu) can be laminated by sputtering and etched by wet-etching to form the gate electrode 113 in each of the R, G, and B subpixels. Thereafter, an organic material such as photo acrylic, or an inorganic material such as SiNx or SiOx can be laminated on the gate electrode 113 to form the interlayered insulating layer 146, and then the interlayered insulating layer 146 and the gate insulating layer 144 on the source region 112b and the drain region 112c of the semiconductor pattern 112 can be dry-etched to form a contact hole.

Subsequently, a metal such as Cr, Mo, Ta, Cu, Ti, Al, or Al alloy can be deposited by sputtering and etched to form the source electrode 114 and the drain electrode 115 that are in ohmic contact with the source region 112b and the drain region 112c of the semiconductor pattern 112 through the respective contact holes in each of the R, G, and B subpixels.

Then, as shown in FIG. 6B, an organic material such as photo acrylic can be deposited on the source electrode 114 and the drain electrode 115 to form the planarization layer 148, and then the planarization layer 148 on the drain electrode 115 can be dry-etched to form a contact hole.

Thereafter, a metal or metal oxide can be deposited on the planarization layer 148 by sputtering and etched by wet-etching to form the 1R electrode 132R, the 1G electrode 132G, and the 1B electrode 132B that are electrically connected to the drain electrodes 115 through the contact holes in the R, G, and B subpixels, respectively. At least one of an inorganic insulating material such as SiNx or SiOx, an organic insulating material such as BCB (benzocyclobutene), acryl resin, epoxy resin, phenolic resin, polyamide resin, or polyimide resin, and a photosensitive agent containing a black pigment can be laminated and etched by dry-etching to form the bank layer 152.

Next, an organic light emitting material can be coated in each of the R, G, and B subpixels on the bank layer 152 and the 1R electrode 132R, the 1G electrode 132G, and the 1B electrode 132B to form the organic layers 134R, 134G, and 134B. For example, the organic layers 134R, 134G, and 134B can be formed integrally as a common layer across the subpixels, but embodiments are not limited thereto.

Then, as shown in FIG. 6C, an alloy such as LiF/Al, CsF/Al, Mg:Ag, Ca/Ag, Ca:Ag, LiF/Mg:Ag, LiF/Ca/Ag, or LiF/Ca:Ag can be deposited at a thickness of about 50 Å to 1500 Å, preferably about 100 Å to 1000 Å in the R, G, and B subpixels on the organic layers 134R, 134G, and 134B by sputtering to form the 2R electrode 135R, the 2G electrode 135G, and the 2B electrode 135B in the R, G, and B subpixels. At this time, the 2R electrode 135R, the 2G electrode 135G, and the 2B electrode 135B can also be formed on the bank layer 152 in the boundary regions of the R, G, and B subpixels. For example, the 2R electrode 135R, the 2G electrode 135G, and the 2B electrode 135B can be formed integrally as a common layer across the subpixels, but embodiments are not limited thereto.

Subsequently, a metal such as AgMg can be deposited at a thickness of about 50 Å to 1500 Å, preferably about 100 Å to 1,000 Å on the 2R electrode 135R, the 2G electrode 135G, and the 2B electrode 135B to form the 3R electrode 136R, the 3G electrode 136G, and the 3B electrode 136B in the R, G, and B subpixels. For example, the 3R electrode 136R, the 3G electrode 136G, and the 3B electrode 136B can be formed integrally as a common layer across the subpixels, but embodiments are not limited thereto.

Then, as shown in FIG. 6D, an organic material with low surface energy or low adhesion to metal can be coated onto the 3B electrode 136B of the B subpixel using a mask to form the metal patterning layer 138 on the 3B electrode 136B. In this way, metal will not stick to the metal patterning layer 138 on the 3B electrode 136B and/or can be easily removed.

Subsequently, as shown in FIG. 6E, a metal oxide such as ITO or IZO can be deposited on the R, G, and B subpixels at a thickness of about 50 Å to 4000 Å, preferably about 100 Å to 3000 Å. At this time, since no metal is deposited on the metal patterning layer 138, the 4R electrode 137R and the 4G electrode 137G can be formed on the 3R electrode 136R, the 3G electrode 136G of the R and G subpixels and the bank layer 152, excluding the metal patterning layer 138. In other words, the metal oxide layer will have a hole or a gap corresponding to the metal patterning layer 138 and will stay adhered to the 3R electrode 136R and the 3G electrode 136G.

Then, as shown in FIG. 6F, an inorganic material such as SiOx or SiNx can be laminated over the entire R, G, and B subpixels to form a first encapsulation layer 162, and then an organic insulating material such as acrylic resin, epoxy resin, polyimide, polyethylene, or silicon oxycarbon (SiOC) can be laminated on the first encapsulation layer 162 to form the second encapsulation layer 164. Next, an inorganic material such as SiOx or SiNx can be laminated on the second encapsulation layer 164 to form the third encapsulation layer 166, thereby completing the display apparatus 100.

As described above, in the method of manufacturing the display apparatus 100 according to an embodiment of the present invention, since the 4R electrode 137R and the 4G electrode 137G are formed in the R and G subpixels using the metal patterning layer 138, there is no need for a separate photolithography process. Accordingly, the manufacturing processes can be simplified, thereby reducing a production cost, reducing energy consumption and reducing use of etchant or developer that causes environmental pollution is minimized, thereby making it possible to be eco-friendly.

In the first embodiment of the present invention, the three-layered cathode electrode is formed in the R and G subpixels, and the two-layered cathode electrode and the metal patterning layer are formed in the B subpixel. However, embodiments of the present invention are not limited to this structure but can be applied to various structures.

Below, other structures of the present invention are described according to various embodiments.

FIG. 7 is a cross-sectional view illustrating a display apparatus according to a second embodiment of the present invention. For example, in FIG. 7, the metal patterning layer 238 is formed in the G subpixel.

As shown in FIG. 7, a buffer layer 242 can be formed on a substrate 240, and a thin film transistor T can be formed in each of the R, G, and B subpixels on the buffer layer 242.

The thin film transistor T can include a semiconductor pattern 212, a gate electrode 213, a source electrode 214, and a drain electrode 215 that are disposed over the buffer layer 242.

A planarization layer 248 can be disposed on the thin film transistor T, and a bank layer 252 can be disposed on the planarization layer 248.

The bank layer 252 can be disposed between the R, G, and B subpixels, and organic light emitting elements 230R, 230G, and 230B can be disposed in the R, G, and B subpixels, respectively.

The R organic light emitting element 230R of the R subpixel can include a 1R electrode 232R disposed on the planarization layer 248, an R organic layer 234R disposed on the 1R electrode 232R, a 2R electrode 235R disposed on the R organic layer 234R, a 3R electrode 236R disposed on the 2R electrode 235R, and a 4R electrode 237R disposed on the 3R electrode 236R.

The G organic light emitting element 230G of the G subpixel can include a 1G electrode 232G disposed on the planarization layer 248, a G organic layer 234G disposed on the 1G electrode 232G, a 2G electrode 235G disposed on the G organic layer 234G, a 3G electrode 236G disposed on the 2G electrode 235G, and a metal patterning layer 238 disposed on the 3G electrode 236G.

The B organic light emitting element 230B of the B subpixel can include a 1B electrode 232B disposed on the planarization layer 248, a B organic layer 234B disposed on the 1B electrode 232B, a 2B electrode 235B disposed on the B organic layer 234B, a 3B electrode 236B disposed on the 2B electrode 235B, and a 4B electrode 237B disposed on the 3B electrode 236B.

The 1R electrode 232R of the R organic light emitting element 230R, the 1G electrode 232G of the G organic light emitting element 230G, and the 1B electrode 232B of the B organic light emitting element 230B can be formed of a metal or metal alloy and reflect light emitted from the organic layers 234R, 234G, and 234B. In addition, the 1R electrode 232R, the 1G electrode 232G, and the 1B electrode 232B can include a transparent metal oxide with a high work function, such as ITO or IZO. In this case, each of the 1R, 1G, and 1B electrodes 232R, 232G, and 232B may further include an opaque conductive material to function as a reflective electrode that reflects light.

The 2R electrode 235R, the 3R electrode 236R, and the 4R electrode 237R of the R organic light emitting element 230R, the 2G electrode 235G and the 3G electrode 236G of the G organic light emitting element 230G, the 2B electrode 235B, the 3B electrode 236B, and the 4B electrode 237B of the B organic light emitting element 230B can be formed of a semi-transmissive conductive layer, so that a part of light emitted from the organic layers 234R, 234G, and 234B is transmitted and output upward, and another part of the light is reflected downward (e.g., reflected inside the display apparatus 200).

The 2R electrode 235R, the 2G electrode 235G, and the 2B electrode 235B can be formed integrally. Accordingly, the 2R electrode 235R, the 2G electrode 235G, and the 2B electrode 235B can also be formed on the upper surface of the bank layer 252.

The 3R electrode 236R, the 3G electrode 236G, and the 3B electrode 236B can be formed integrally. Accordingly, the 3R electrode 236R, the 3G electrode 236G, and the 3B electrode 236B can also be formed on the bank layer 252.

The 4R electrode 237R and the 4B electrode 237B can be formed integrally. The metal patterning layer 238 can be formed of an organic material with low surface energy or low adhesion to metal.

As the metal patterning layer 238 can be provided to pattern a metal layer using a self-aligned patterning method, the metal patterning layer 238 can be provided such that without a separate etching process of a metal layer, based on an interface characteristics with the metal patterning layer 238, a metal layer deposited is removed on the metal patterning layer 238 or a metal is prevented from being deposited on the metal patterning layer 238, thereby patterning the metal layer. Since no metal is deposited on the upper surface of the metal patterning layer 238, a metal layer is formed only on the R and B subpixels and the bank layer 252. Thus, the 4R electrode 237R and the 4B electrode 237B are formed in the R and B subpixels, respectively, and a 4G electrode is not formed in the G subpixel.

An encapsulation layer 260 can be formed on the organic light emitting elements 230R, 230G, and 230B. The encapsulation layer 260 can be formed of a first encapsulation layer 262 made of an inorganic material, a second encapsulation layer 264 made of an organic material, and a third encapsulation layer 266 made of an inorganic material.

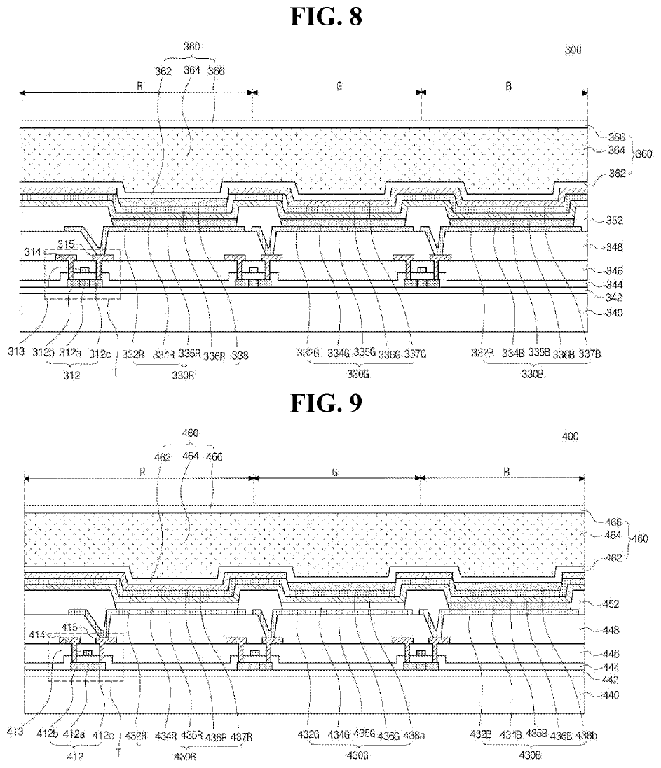

FIG. 8 is a cross-sectional view illustrating a display apparatus according to a third embodiment of the present invention. For example, in FIG. 8, the metal patterning layer 338 is formed in the R subpixel.

As shown in FIG. 8, a buffer layer 342 can be formed on a substrate 340, and a thin film transistor T can be formed in each of the R, G, and B subpixels on the buffer layer 342.

The thin film transistor T can include a semiconductor pattern 312, a gate electrode 313, a source electrode 314, and a drain electrode 315 that are disposed over the buffer layer 342.

A planarization layer 348 can be disposed on the thin film transistor T, and a bank layer 352 can be disposed on the planarization layer 348.

The bank layer 352 can be disposed between the R, G, and B subpixels, and organic light emitting elements 330R, 330G, and 330B can be disposed in the R, G, and B subpixels, respectively.

The R organic light emitting element 330R of the R subpixel can include a 1R electrode 332R disposed on the planarization layer 348, an R organic layer 334R disposed on the 1R electrode 332R, a 2R electrode 335R disposed on the R organic layer 334R, a 3R electrode 336R disposed on the 2R electrode 335R, and a metal patterning layer 338 disposed on the 3R electrode 236R.

The G organic light emitting element 330G of the G subpixel can include a 1G electrode 332G disposed on the planarization layer 348, a G organic layer 334G disposed on the 1G electrode 332G, a 2G electrode 335G disposed on the G organic layer 334G, a 3G electrode 336G disposed on the 2G electrode 335G, and a 4G electrode 337G disposed on the 3G electrode 336G.

The B organic light emitting element 330B of the B subpixel can include a 1B electrode 332B disposed on the planarization layer 348, a B organic layer 334B disposed on the 1B electrode 332B, a 2B electrode 335B disposed on the B organic layer 334B, a 3B electrode 336B disposed on the 2B electrode 335B, and a 4B electrode 337B disposed on the 3B electrode 336B.

The 1R electrode 332R of the R organic light emitting element 330R, the 1G electrode 332G of the G organic light emitting element 330G, and the 1B electrode 332B of the B organic light emitting element 330B can be formed of a metal or metal alloy and reflect light emitted from the organic layers 334R, 334G, and 334B. In addition, the 1R electrode 332R, the 1G electrode 332G, and the 1B electrode 332B can include a transparent metal oxide with a high work function, such as ITO or IZO. In this case, each of the 1R, 1G, and 1B electrodes 332R, 332G, and 332B may further include an opaque conductive material to function as a reflective electrode that reflects light.

The 2R electrode 335R and the 3R electrode 336R of the R organic light emitting element 330R, the 2G electrode 335G, the 3G electrode 336G, and the 4G electrode 337G of the G organic light emitting element 330G, the 2B electrode 335B, the 3B electrode 336B, and the 4B electrode 337B of the B organic light emitting element 330B can be formed of a semi-transmissive conductive layer, so that so that a part of light emitted from the organic layers 334R, 334G, and 334B is transmitted and output upward, and another part of the light is reflected downward (e.g., reflected inside the display apparatus 300).

The 2R electrode 335R, the 2G electrode 335G, and the 2B electrode 335B can be formed integrally. Accordingly, the 2R electrode 335R, the 2G electrode 335G, and the 2B electrode 335B can also be formed on the upper surface of the bank layer 352.

The 3R electrode 336R, the 3G electrode 336G, and the 3B electrode 336B can be formed integrally. Accordingly, the 3R electrode 336R, the 3G electrode 336G, and the 3B electrode 336B can also be formed on the bank layer 352.

The 4G electrode 337G and the 4B electrode 337B can be formed integrally. The metal patterning layer 338 can be formed of an organic material with low surface energy or low adhesion to metal.

As the metal patterning layer 338 can be provided to pattern a metal layer using a self-aligned patterning method, the metal patterning layer 338 can be provided such that without a separate etching process of a metal layer, based on an interface characteristics with the metal patterning layer 338, a metal layer deposited is removed on the metal patterning layer 338 or a metal is prevented from being deposited on the metal patterning layer 338, thereby patterning the metal layer. Since no metal is deposited on the upper surface of the metal patterning layer 338, a metal layer is formed only on the G and B subpixels and the bank layer 352, Thus, the 4G electrode 337G and the 4B electrode 337B are formed in the G and B subpixels, respectively, and a 4R electrode is not formed in the R subpixel. For example, the cathode in the R subpixel has two layers, and the cathodes in the G and B subpixels have three layers.

An encapsulation layer 360 can be formed on the organic light emitting elements 330R, 330G, and 330B. The encapsulation layer 360 can be formed of a first encapsulation layer 362 made of an inorganic material, a second encapsulation layer 364 made of an organic material, and a third encapsulation layer 366 made of an inorganic material.

FIG. 9 is a cross-sectional view illustrating a display apparatus according to a fourth embodiment of the present invention. For example, in FIG. 9, the metal patterning layer 438a is formed in the G subpixel, and the metal patterning layer 438b is formed in the B subpixel.

As shown in FIG. 9, a buffer layer 442 can be formed on a substrate 440, and a thin film transistor T can be formed in each of the R, G, and B subpixels on the buffer layer 442.

The thin film transistor T can include a semiconductor pattern 412, a gate electrode 413, a source electrode 414, and a drain electrode 415 that are disposed over the buffer layer 442.

A planarization layer 448 can be disposed on the thin film transistor T, and a bank layer 452 can be disposed on the planarization layer 448.

The bank layer 452 can be disposed between the R, G, and B subpixels, and organic light emitting elements 430R, 430G, and 430B can be disposed in the R, G, and B subpixels, respectively.

The R organic light emitting element 430R of the R subpixel can include a 1R electrode 432R disposed on the planarization layer 448, an R organic layer 434R disposed on the 1R electrode 432R, a 2R electrode 435R disposed on the R organic layer 434R, a 3R electrode 436R disposed on the 2R electrode 435R, and a 4R electrode 437R disposed on the 3R electrode 436R.

The G organic light emitting element 430G of the G subpixel can include a 1G electrode 432G disposed on the planarization layer 448, a G organic layer 434G disposed on the 1G electrode 432G, a 2G electrode 435G disposed on the G organic layer 434G, a 3G electrode 436G disposed on the 2G electrode 435G, and a first metal patterning layer 438a disposed on the 3G electrode 436G.

The B organic light emitting element 430B of the B subpixel can include a 1B electrode 432B disposed on the planarization layer 448, a B organic layer 434B disposed on the 1B electrode 432B, a 2B electrode 435B disposed on the B organic layer 434B, a 3B electrode 436B disposed on the 2B electrode 435B, and a second metal patterning layer 438b disposed on the 3B electrode 436B.

The 1R electrode 432R of the R organic light emitting element 430R, the 1G electrode 432G of the G organic light emitting element 430G, and the 1B electrode 432B of the B organic light emitting element 430B can be formed of a metal or metal alloy and reflect light emitted from the organic layers 434R, 434G, and 434B. In addition, the 1R electrode 432R, the 1G electrode 432G, and the 1B electrode 432B can include a transparent metal oxide with a high work function, such as ITO or IZO. In this case, each of the 1R, 1G, and 1B electrodes 432R, 432G, and 432B may further include an opaque conductive material to function as a reflective electrode that reflects light.

The 2R electrode 435R, the 3R electrode 436R, and the 4R electrode 437R of the R organic light emitting element 430R, the 2G electrode 435G and the 3G electrode 436G of the G organic light emitting element 430G, the 2B electrode 435B and the 3B electrode 436B of the B organic light emitting element 430B can be formed of a semi-transmissive conductive layer, and a part of light emitted from the organic layers 434R, 434G, and 434B is transmitted and output upward, and another part of the light is reflected downward (e.g., reflected inside the display apparatus 400).

The 2R electrode 435R, the 2G electrode 435G, and the 2B electrode 435B can be formed integrally. Accordingly, the 2R electrode 435R, the 2G electrode 435G, and the 2B electrode 435B can also be formed on the upper surface of the bank layer 452.

The 3R electrode 436R, the 3G electrode 436G, and the 3B electrode 436B can be formed integrally. Accordingly, the 3R electrode 436R, the 3G electrode 436G, and the 3B electrode 436B can also be formed on the bank layer 452.

The first and second metal patterning layers 438a and 438b can be formed of an organic material with low surface energy or low adhesion to metal.

As the first and second metal patterning layers 438a and 438b can be provided to pattern a metal layer using a self-aligned patterning method, the first and second metal patterning layers 438a and 438b can be provided such that without a separate etching process of a metal layer, based on an interface characteristics with the first and second metal patterning layers 438a and 438b, a metal layer deposited is removed on the first and second metal patterning layers 438a and 438b or a metal is prevented from being deposited on the first and second metal patterning layers 438a and 438b, thereby patterning the metal layer. Since no metal is deposited on the upper surfaces of the first and second metal patterning layers 438a and 438b, a metal layer is formed only on the R subpixel and the bank layer 452. Thus, the 4R electrode 437R is formed in the R subpixel, and a 4G electrode and a 4B electrode are not formed in the G and B subpixels.

An encapsulation layer 460 can be formed on the organic light emitting elements 430R, 430G, and 430B. The encapsulation layer 460 can be formed of a first encapsulation layer 462 made of an inorganic material, a second encapsulation layer 464 made of an organic material, and a third encapsulation layer 466 made of an inorganic material.

Meanwhile, in this embodiment, the cathode electrode of the R subpixel is formed of the three layers of electrodes 435R, 436R, and 437R, and the cathode electrodes of the G and B subpixels are formed of the two layers of electrodes 435G and 436G, and 435B and 436B, respectively, but embodiments are not limited to this. Alternatively, the cathode electrode of the G subpixel can be formed of three layers of electrodes, and the cathode electrodes of the R and B subpixels can each be formed of two layers of electrodes. Alternatively, the cathode electrode of the B subpixel can be formed of three layers of electrodes, and the cathode electrodes of the R and G subpixels can each be formed of two layers of electrodes.

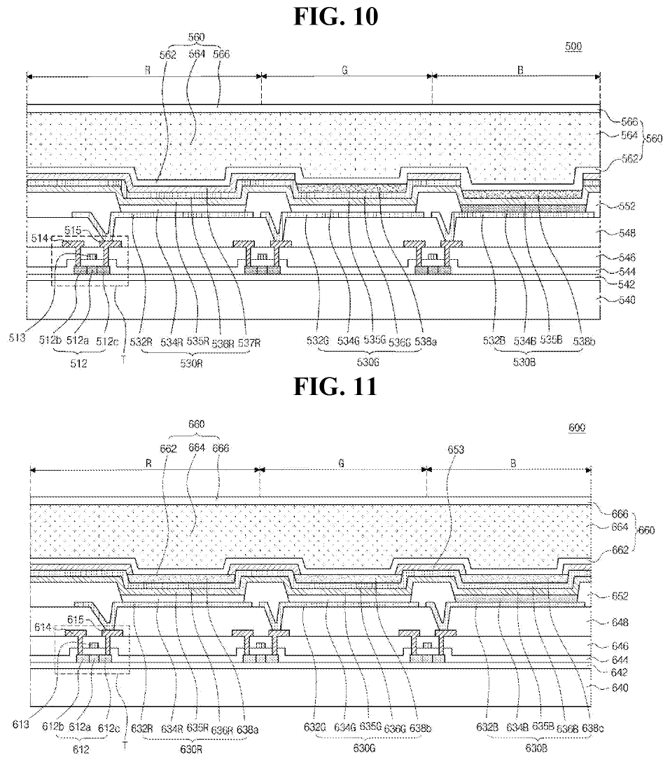

FIG. 10 is a cross-sectional view illustrating a display apparatus according to a fifth embodiment of the present invention. For example, in FIG. 10, the metal patterning layer 438a is formed in the G subpixel, and the metal patterning layer 438b is formed in the B subpixel, but the cathode in the G subpixel has two layers while the cathode in the B subpixel has one layer.

As shown in FIG. 10, a buffer layer 542 can be formed on a substrate 540, and a thin film transistor T can be formed in each of the R, G, and B subpixels on the buffer layer 542.

The thin film transistor T can include a semiconductor pattern 512, a gate electrode 513, a source electrode 514, and a drain electrode 515 that are disposed over the buffer layer 542.

A planarization layer 548 can be disposed on the thin film transistor T, and a bank layer 552 can be disposed on the planarization layer 548.

The bank layer 552 can be disposed between the R, G, and B subpixels, and organic light emitting elements 530R, 530G, and 530B can be disposed in the R, G, and B subpixels, respectively.

The R organic light emitting element 530R of the R subpixel can include a 1R electrode 532R disposed on the planarization layer 548, an R organic layer 534R disposed on the 1R electrode 532R, a 2R electrode 535R disposed on the R organic layer 534R, a 3R electrode 536R disposed on the 2R electrode 535R, and a 4R electrode 537R disposed on the 3R electrode 536R.

The G organic light emitting element 530G of the G subpixel can include a 1G electrode 532G disposed on the planarization layer 548, a G organic layer 534G disposed on the 1G electrode 532G, a 2G electrode 535G disposed on the G organic layer 534G, a 3G electrode 536G disposed on the 2G electrode 535G, and a first metal patterning layer 538a disposed on the 3G electrode 536G.

The B organic light emitting element 530B of the B subpixel can include a 1B electrode 532B disposed on the planarization layer 548, a B organic layer 534B disposed on the 1B electrode 532B, a 2B electrode 535B disposed on the B organic layer 534B, and a second metal patterning layer 538b disposed on the 2B electrode 535B.

The 1R electrode 532R of the R organic light emitting element 530R, the 1G electrode 532G of the G organic light emitting element 530G, and the 1B electrode 532B of the B organic light emitting element 530B can be made of a metal or metal alloy and reflect light emitted from the organic layers 534R, 534G, and 534B. In addition, the 1R electrode 532R, the 1G electrode 532G, and the 1B electrode 532B can include a transparent metal oxide with a high work function, such as ITO or IZO. In this case, each of the 1R, 1G, and 1B electrodes 532R, 532G, and 532B may further include an opaque conductive material to function as a reflective electrode that reflects light.

The 2R electrode 535R, the 3R electrode 536R, and the 4R electrode 537R of the R organic light emitting element 530R, the 2G electrode 535G and the 3G electrode 536G of the G organic light emitting element 530G, the 2B electrode 535B of the B organic light emitting element 530B can be formed of a semi-transmissive conductive layer, so that a part of light emitted from the organic layers 534R, 534G, and 534B is transmitted and output upward, and another part of the light is reflected downward (e.g., reflected inside the display apparatus 500).

The 2R electrode 535R, the 2G electrode 535G, and the 2B electrode 535B can be formed integrally. Accordingly, the 2R electrode 535R, the 2G electrode 535G, and the 2B electrode 535B can also be formed on the upper surface of the bank layer 552.

The 3R electrode 536R and the 3G electrode 536G can be formed integrally. Accordingly, the 3R electrode 536R and the 3G electrode 536G can also be formed on the bank layer 552.

The first and second metal patterning layers 538a and 538b can be made of an organic material with low surface energy or low adhesion to metal.

As the first and second metal patterning layers 538a and 538b can be provided to pattern a metal layer using a self-aligned patterning method, the first and second metal patterning layers 538a and 538b can be provided such that without a separate etching process of a metal layer, based on an interface characteristics with the first and second metal patterning layers 538a and 538b, a metal layer deposited is removed on the first and second metal patterning layers 538a and 538b or a metal is prevented from being deposited on the first and second metal patterning layers 538a and 538b, thereby patterning the metal layer.

Since no metal is deposited on the upper surfaces of the first and second metal patterning layers 538a and 538b, three metal layers are formed only in the R subpixel. Thus, the 3R electrode 536R and the 4R electrode 537R are formed in the R subpixel, but the 3G electrode 536G is formed in the G subpixel and a 4G electrode is not formed in the G subpixel. In addition, the 2G electrode 535B is formed in the B subpixel, and a 3B electrode and a 4B electrode are not formed in the B subpixel.

As such, in this embodiment, the three-layered cathode electrode is formed in the R subpixel with the longest wavelength, the two-layered cathode electrode is formed in the G subpixel with the medium wavelength, and the one-layered cathode electrode is formed in the B-subpixel with the shortest wavelength. In other words, the R subpixel with the longest wavelength has the longest resonance distance of light, the G subpixel with the medium wavelength has the medium resonance distance of light, and the B subpixel with the shortest wavelength has the shortest resonance distance of light, so that the constructive interference of each of the red light, the green light, and the blue light can be maximized, thereby optimizing the light extraction efficiency for each of the R, G, and B subpixels.

Referring again to FIG. 10, an encapsulation layer 560 can be formed on the organic light emitting elements 530R, 530G, and 530B. The encapsulation layer 560 can be formed of a first encapsulation layer 562 made of an inorganic material, a second encapsulation layer 564 made of an organic material, and a third encapsulation layer 566 made of an inorganic material.

Meanwhile, in this embodiment, the cathode electrode of the R subpixel is formed of the three layers of electrodes 535R, 535G, and 535B, the cathode electrode of the G subpixel is formed of the two layers of electrodes 535G and 536G, and the cathode electrode of the B subpixel is formed of the one layer of electrode 535B, but the present invention is not limited to this configuration.

For example, the cathode electrode of the R subpixel can be formed of one layer of electrode, the cathode electrode of the G subpixel can be formed of two layers of electrodes, and the cathode electrode of the B subpixel can be formed of three layers of electrodes. Alternatively, the cathode electrode of the R subpixel can be formed of two layers of electrodes, the cathode electrode of the G subpixel can be formed of three layers of electrodes, and the cathode electrode of the B subpixel can be formed of one layer of electrodes.

In other words, one of the R, G, and B subpixels can be formed of a one-layered cathode electrode, another subpixel can be formed of a two-layered cathode electrode, and the remaining subpixel can be formed of a three-layered cathode electrode. In addition, the metal patterning layer can be disposed on a cathode electrode formed of one layer of electrode and a cathode electrode formed of two layers of electrodes. Also, according to an embodiment, the metal patterning layer can be disposed on a cathode electrode formed of three or more layers.

FIG. 11 is a cross-sectional view illustrating a display apparatus according to a sixth embodiment of the present invention. For example, in FIG. 11, a metal patterning layer can be individually formed in each of the three subpixels. Alternatively, the metal patterning layer can be formed as a common layer extending across the three subpixels.

As shown in FIG. 11, a buffer layer 642 can be formed on a substrate 640, and a thin film transistor T can be formed in each of the R, G, and B subpixels on the buffer layer 642.

The thin film transistor T can include a semiconductor pattern 612, a gate electrode 613, a source electrode 614, and a drain electrode 615 that are disposed over the buffer layer 642.

A planarization layer 648 can be disposed on the thin film transistor, and a bank layer 652 can be disposed on the planarization layer 648.

The bank layer 652 can be disposed between the R, G, and B subpixels, and organic light emitting elements 630R, 630G, and 630B can be disposed in the R, G, and B subpixels, respectively.

The R organic light emitting element 630R of the R subpixel can include a 1R electrode 632R disposed on the planarization layer 648, an R organic layer 634R disposed on the 1R electrode 632R, a 2R electrode 635R disposed on the R organic layer 634R, and a 3R electrode 636R disposed on the 2R electrode 635R.

The G organic light emitting element 630G of the G subpixel can include a 1G electrode 632G disposed on the planarization layer 648, a G organic layer 634G disposed on the 1G electrode 632G, a 2G electrode 635G disposed on the G organic layer 634G, and a 3G electrode 636G disposed on the 2G electrode 635G.

The B organic light emitting element 630B of the B subpixel can include a 1B electrode 632B disposed on the planarization layer 648, a B organic layer 634B disposed on the 1B electrode 632B, a 2B electrode 635B disposed on the B organic layer 634B, and a 3B electrode 636B disposed on the 2B electrode 635B.

A first metal patterning layer 638a can be disposed on the 3R electrode 636R of the R subpixel, a second metal patterning layer 638b can be disposed on the 3G electrode 636G of the G subpixel, and a third metal patterning layer 638c can be disposed on the 3B electrode 636B of the B subpixel.

The 1R electrode 632R of the R organic light emitting element 630R, the 1G electrode 632G of the G organic light emitting element 630G, and the 1B electrode 632B of the B organic light emitting element 630B can be formed of a metal or metal alloy and reflect light emitted from the organic layers 634R, 634G, and 634B. In addition, the 1R electrode 632R, the 1G electrode 632G, and the 1B electrode 632B can include a transparent metal oxide with a high work function, such as ITO or IZO. In this case, each of the 1R, 1G, and 1B electrodes 632R, 632G, and 632B may further include an opaque conductive material to function as a reflective electrode that reflects light.

The 2R electrode 635R and the 3R electrode 636R of the R organic light emitting element 630R, the 2G electrode 635G and the 3G electrode 636G of the G organic light emitting element 630G, and the 2B electrode 635B and the 3B electrode 636B of the B organic light emitting element 630B can be formed of a semi-transmissive conductive layer, so that a part of light emitted from the organic layers 634R, 634G, and 634B is transmitted and output upward, and another part of the light is reflected downward (e.g., reflected inside the display apparatus 600).

The 2R electrode 635R, the 2G electrode 635G, and the 2B electrode 635B can be formed integrally. Accordingly, the 2R electrode 635R, the 2G electrode 635G, and the 2B electrode 635B can also be formed on the upper surface of the bank layer 652.

The 3R electrode 636R, the 3G electrode 636G, and the 3B electrode 636B can be formed integrally. Accordingly, the 3R electrode 636R, the 3G electrode 636G, and the 3B electrode 636B can also be formed on the bank layer 652.

The first to third metal patterning layers 638a, 638b, and 638c can be formed only on the 3R, 3G, and 3B electrode 636R, 636G, and 636B of the R, G and B subpixels, respectively, and may not be formed over the bank layer 652.

The first to third metal patterning layers 638a, 638b, and 638c can be formed of an organic material with low surface energy or low adhesion to metal. As the first to third metal patterning layers 638a, 638b, and 638c can be provided to pattern a metal layer using a self-aligned patterning method, the first to third metal patterning layers 638a, 638b, and 638c can be provided such that without a separate etching process of a metal layer, based on an interface characteristics with the first to third metal patterning layers 638a, 638b, and 638c, a metal layer deposited is removed on the first to third metal patterning layers 638a, 638b, and 638b or a metal is prevented from being deposited on the first to third metal patterning layers 638a, 638b, and 638b, thereby patterning the metal layer.

Since no metal is deposited on the upper surfaces of the 3R electrode 636R, the 3G electrode 636G, and the 3B electrode 636B, the cathode electrodes of the R, G, and B subpixels are each formed of two metal layers, and a metal layer 653 is formed on the 3R electrode 636R, the 3G electrode 636G, and the 3B electrode 636B over the bank layer 652 and formed on parts of side surfaces of the 3R electrode 636R, the 3G electrode 636G, and the 3B electrode 636B.

In other words, in the display apparatus 600 according to this embodiment, the second electrodes 635R, 635G, and 635B, the third electrodes 636R, 636G, and 636B, and the metal layer 653 are disposed over the bank layer 652. At this time, the second electrodes 635R, 635G, and 635B, and the third electrodes 636R, 636G, and 636B are continuously formed not only over the bank layer 652 but also in the R, G, and B subpixels, while the metal layer 653 is formed only over the bank layer 652 and on parts of the side surfaces of the third electrodes 636R, 636G, and 636B.

As such, the metal layer 653 formed over the bank layer 652 can act as another partition wall dividing the R, G, and B subpixels. In this regard, in the display apparatus 600 of this embodiment, it can be said that a bank layer includes the bank layer 652 made of an organic material, the second electrodes 635R, 635G, and 635B disposed on the bank layer 652, and the third electrodes 636R, 636G, and 636B disposed on the second electrodes 635R, 635G, and 635B, and the metal layer 653 disposed on the third electrodes 636R, 636G, and 636B.

Referring again to FIG. 11, an encapsulation layer 660 can be formed on the organic light emitting elements 630R, 630G, and 630B. The encapsulation layer 660 can be formed of a first encapsulation layer 662 made of an inorganic material, a second encapsulation layer 664 made of an organic material, and a third encapsulation layer 666 made of an inorganic material.

As described above, in the display apparatus according to the present invention, by varying the electrode structure of the organic light emitting elements of the R, G, and B subpixels (e.g., varying a number of the cathode electrodes), the resonance distances of light in the R, G, and B sub-pixels are made different. As a result, the constructive interferences of light according to the wavelengths can be maximized, and the light extraction efficiency in the R, G, and B subpixels can be optimized.

In addition, according to an embodiment of the present invention, since the cathode electrodes of the R, G, and B subpixels are patterned using the metal patterning layer, a separate photolithography process is not required. Therefore, the manufacturing processes can be simplified, thereby reducing a production cost, and use of etchant or developer that causes environmental pollution can be minimized, thereby making it possible to be eco-friendly.

Although the embodiments of the present invention are described above in more detail with reference to the accompanying drawings, the present invention is not necessarily limited to these embodiments, and can be variously modified and implemented without departing from the technical idea of the present invention. Therefore, the embodiments disclosed in the present invention are not intended to limit the technical idea of the present invention, but to explain, and the scope of the technical idea of the present invention is not limited by these embodiments. Therefore, it should be understood that the embodiments described above are illustrative in all respects and not restrictive. The protection scope of the present invention can be construed according to the scope of the claims, and all technical ideas within the scope equivalent thereto should be construed as being included in the scope of the present invention.

What is claimed is:

1. A display apparatus, comprising:
a first subpixel, a second subpixel and a third subpixel disposed on a substrate;
a first organic light emitting element configured to emit a first color of light, a second organic light emitting element configured to emit a second color of light and a third organic light emitting element configured to emit a third color of light disposed in the first, second and third subpixels, respectively;
a first anode, a second anode and a third anode included in the first, second and third organic light emitting elements, and disposed in the first, second and third subpixels, respectively; and
a first cathode, a second cathode and a third cathode included in the first, second and third organic light emitting elements, and disposed in the first, second and third subpixels, respectively,
wherein the first, second and third cathodes include at least one layer, and
wherein at least two cathodes among the first, second and third cathodes have a different number of layers than each other.

2. The display apparatus of claim 1, wherein each of the first cathode and the second cathode includes three layers, and the third cathode includes two layers, and
wherein a metal patterning layer is disposed on the third cathode.

3. The display apparatus of claim 2, wherein the metal patterning layer includes an organic material.

4. The display apparatus of claim 2, further comprising a bank dividing the first, second and third subpixels.

5. The display apparatus of claim 4, wherein at least a portion of each of the first, second and third cathodes overlaps with the bank.

6. The display apparatus of claim 5, wherein the first, second and third cathodes are formed as a common cathode layer across the first, second and third pixels, and
wherein the common cathode layer has a disconnection portion or a hole overlapping with the metal patterning layer in the third subpixel.

7. The display apparatus of claim 1, wherein the first cathode includes three layers, and each of the second cathode and the third cathode includes two layers, and
wherein a first metal patterning layer is disposed on the second cathode, and a second metal patterning layer is disposed on the third cathode.

8. The display apparatus of claim 7, wherein the first and second metal patterning layers include an organic material.

9. The display apparatus of claim 7, further comprising a bank dividing the first, second and third subpixels.

10. The display apparatus of claim 9, wherein at least a portion of each of the first, second and third cathodes overlaps with the bank.

11. The display apparatus of claim 10, wherein the first, second and third cathodes are formed as a common cathode layer across the first, second and third pixels, and
wherein the common cathode layer has a first disconnection portion or a first hole overlapping with the first metal patterning layer in the second subpixel, and a second disconnection portion or a second hole overlapping with the second first metal patterning layer in the third subpixel.

12. The display apparatus of claim 1, wherein the first cathode includes three layers, the second cathode includes two layers, and the third cathode includes one layer, and
wherein a first metal patterning layer is disposed on the second cathode, and a second metal patterning layer is disposed on the third cathode.

13. The display apparatus of claim 12, wherein the first and second metal patterning layers include an organic material.

14. The display apparatus of claim 12, further comprising a bank dividing the first, second and third subpixels.

15. The display apparatus of claim 14, wherein at least a portion of each of the first, second and third cathodes overlaps with the bank.

16. The display apparatus of claim 10, wherein the first, second and third cathodes are formed as a common cathode layer across the first, second and third pixels, and
wherein the common cathode layer has a first disconnection portion or a first hole overlapping with the first metal patterning layer in the second subpixel, and a second disconnection portion or a second hole overlapping with the second first metal patterning layer in the third subpixel.

17. The display apparatus of claim 1, wherein the first, second and third subpixels are different ones of a red subpixel, a green subpixel, and a blue subpixel.

18. A display apparatus, comprising:
a first subpixel, a second subpixel and a third subpixel disposed on a substrate;
a first electrode disposed in each of the first, second and third subpixels;
an organic layer disposed on the first electrode in each of the first, second and third subpixels;
a second electrode disposed on the organic layer in each of the first, second and third subpixels, the second electrode including at least one layer; and
a metal patterning layer disposed on the second electrode of at least one subpixel among the first, second and third subpixels.

19. The display apparatus of claim 18, wherein the metal patterning layer includes an organic material.

20. The display apparatus of claim 18, wherein the second electrode in each of the first subpixel and the second subpixel includes three layers,
wherein the second electrode in the third subpixel includes two layers, and
wherein the metal patterning layer is disposed on the second electrode in the third subpixel.

21. The display apparatus of claim 18, wherein the second electrode in the first subpixel includes three layers,
wherein the second electrode in each of the second subpixel and the third subpixel is includes two layers, and
wherein the metal patterning layer is disposed on the second electrode in each of the second subpixel and the third subpixel.

22. The display apparatus of claim 18, wherein the second electrode in the first subpixel includes three layers, the second electrode in the second subpixel includes two layers, and the second electrode in the third subpixel includes one layer, and
wherein the metal patterning layer is disposed on the second electrode in each of the second subpixel and the third subpixel.

23. The display apparatus of claim 18, wherein the metal patterning layer is disposed on the second electrode in each of the first, second and third subpixels.

24. The display apparatus of claim 18, further comprising a bank layer disposed in a boundary region between the first, second and third subpixels.

25. The display apparatus of claim 24, wherein the bank layer includes:
a portion of the organic layer; and
a portion of the second electrode disposed on the portion of the organic layer.

26. A display apparatus, comprising:
a first subpixel and a second subpixel disposed on a substrate;
a first anode and a second anode disposed in the first and second subpixels, respectively;
a first organic light emitting element configured to emit a first color of light disposed in the first subpixel;
a second organic light emitting element configured to emit a second color of light disposed in the second subpixel; and
a first cathode and a second cathode disposed in the first and second subpixels, respectively,
wherein the first cathode has a different number of layers than the second cathode.
